(19) United States
(12) Patent Application Publication
(10) Pub. No.: US 2026/0223683 A1
(43) Pub. Date: Jul. 30, 2026

(54) SEMICONDUCTOR PACKAGE AND METHOD

(71) Applicant: Taiwan Semiconductor Manufacturing Co., Ltd., Hsinchu (TW)

(72) Inventors: Po-Chen Lai, Hsinchu (TW); Ming-Chih Yew, Hsinchu (TW); Shin-Puu Jeng, Hsinchu (TW); Yu-Sheng Lin, Zhubei (TW)

(21) Appl. No.: 19/542,172

(22) Filed: Feb. 17, 2026

Related U.S. Application Data
(63) Continuation-in-part of application No. 17/663,692, filed on May 17, 2022.

(51) Int. Cl. H10W 42/00; H10W 74/01; H10W 74/10; H10W 90/10

(52) U.S. Cl. CPC H10W 42/121; H10W 74/01; H10W 74/111; H10W 90/10

(57) ABSTRACT

A semiconductor package including supporting structures and a method of forming is provided. The semiconductor package may include an interposer, one or more package components bonded to the interposer, an encapsulant on the interposer, and a plurality of supporting structures on the interposer. One or more supporting structures may be disposed on each corner of the interposer in a top view. The plurality of supporting structures may comprise a first metal and may be embedded in the encapsulant.

### PRIORITY CLAIM AND CROSS-REFERENCE

This application is a continuation-in-part of U.S. patent application Ser. No. 17/663,692, filed on May 17, 2022, which application is hereby incorporated herein by reference.

### BACKGROUND

The formation of integrated circuits includes forming integrated circuit devices on semiconductor wafers, and then sawing the semiconductor wafers into device dies. The device dies may be bonded to package components such as interposers, package substrates, printed circuit boards, or the like. To protect the device dies and the bonding structures that bond a device die to a package component, an encapsulant such as a molding compound, an underfill, or the like, may be used to encapsulate the device dies.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-11, 12A, 12B, 13-15, 16A, 16B, 17A, 17B, 18A, 18B, 19, and 20 illustrate the cross-sectional views and top views of intermediate stages in the formation of a package including supporting structures in accordance with some embodiments.

FIG. 21 illustrates a process flow for forming a package in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A semiconductor package with supporting structures and the method of forming the same are provided. In accordance with some embodiments of the present disclosure, a device die is bonded to an underlying package component, such as an organic interposer. The device die is molded in an encapsulant, such as a molding compound. Supporting structures are also molded in the encapsulant, and are located close to the corners of the resulting package. The supporting structures may comprise a material with a high degree of hardness, so that supporting structures provide support to nearby corner regions of the encapsulant in order to prevent or reduce cracking and/or delamination of encapsulant in nearby corner regions. The prevention or reduction of cracking and/or delamination of encapsulant leads to better long-term reliability of the semiconductor package.

Embodiments discussed herein are to provide examples to enable making and using the subject matter of this disclosure, and a person having ordinary skill in the art will readily understand modifications that can be made while remaining within contemplated scopes of different embodiments. Throughout the various views and illustrative embodiments, like reference numbers are used to designate like features. Although method embodiments may be discussed as being performed in a particular order, other method embodiments may be performed in any logical order.

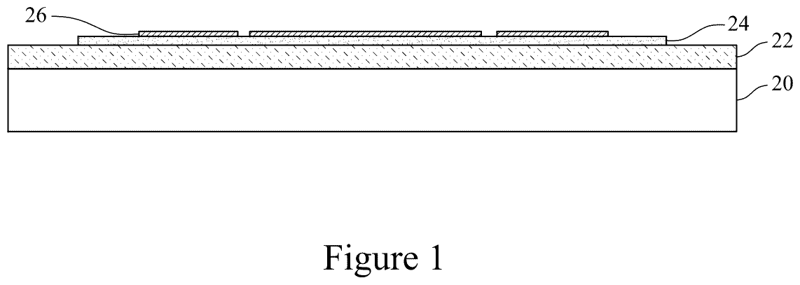

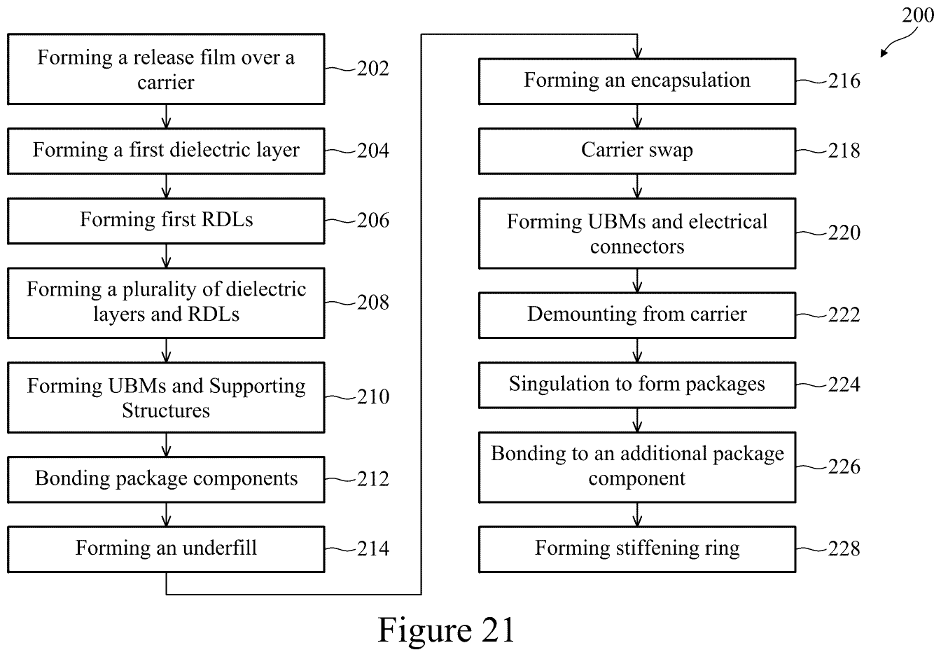

FIGS. 1-11, 12A, 12B, 13-15, 16A, 16B, 17A, 17B, 18A, 18B, 19, and 20 illustrate the cross-sectional views and top views of intermediate stages in the formation of a package including supporting structures in accordance with some embodiments. The corresponding processes are also reflected schematically in the process flow shown in FIG. 21.

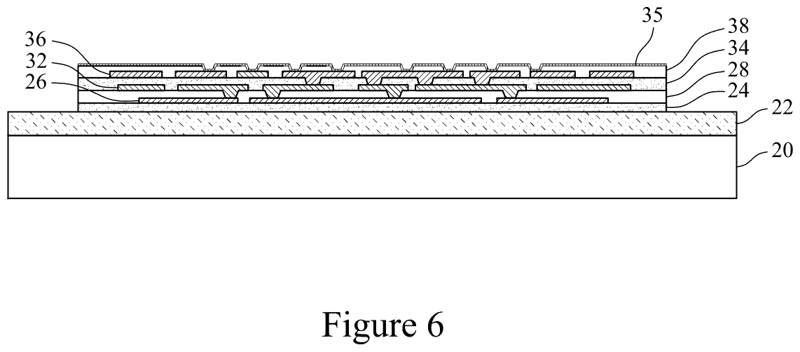

FIGS. 1 through 9 illustrate the cross-sectional views of the formation of interposer 46 and supporting structures 43 as shown in FIG. 6. In some embodiments, interposer 46 is an organic interposer, which includes organic dielectric layers and redistribution lines formed in the organic dielectric layers. In some embodiments, interposer 46 is a semiconductor interposer, which may include a semiconductor substrate, such as silicon substrate, through-silicon vias in the semiconductor substrate, and metal lines/vias and/or redistribution lines.

Referring to FIG. 1, release film 22 is formed on carrier 20. The respective process is illustrated as process 202 in the process flow 200 as shown in FIG. 21. Carrier 20 may be a glass carrier, an organic carrier, or the like. Carrier 20 may have a round top-view shape, and may have a size of a common silicon wafer. Release film 22 may be formed of a polymer-based material, such as a Light-To-Heat-Conversion (LTHC) material, which may be removed along with carrier 20 from the overlying structures that will be formed in subsequent steps. In some embodiments, release film 22 comprises an epoxy-based thermal-release material. Release film 22 may be coated onto carrier 20.

Insulating layer 24 is formed on release film 22. The respective process is illustrated as process 204 in the process flow 200 as shown in FIG. 21. In some embodiments, insulating layer 24 is formed of or comprises an organic material, which may also be a photo-sensitive material such as polybenzoxazole (PBO), polyimide, benzocyclobutene (BCB), or the like. In some embodiments, insulating layer 24 is formed of or comprises an inorganic dielectric material such as silicon oxide, silicon nitride, silicon carbide, silicon oxynitride, silicon oxycarbide, silicon oxycarbonitride, Un-doped Silicate Glass (USG), or the like.

Redistribution lines (RDLs) 26 are formed over insulating layer 24. The respective process is illustrated as process 206 in the process flow 200 as shown in FIG. 21. The formation of RDLs 26 may include forming a seed layer (not shown) over insulating layer 24, forming a patterned mask (not shown) such as a photoresist over the seed layer, and performing a plating process on the exposed seed layer. The patterned mask and the portions of the seed layer covered by the patterned mask are removed, leaving RDLs 26 as shown in FIG. 1. In some embodiments, the seed layer includes a titanium layer and a copper layer over the titanium layer. The seed layer may be formed using, for example, Physical Vapor Deposition (PVD). The plating process may be performed using, for example, Electro Chemical Plating (ECP), electro-less plating, or the like.

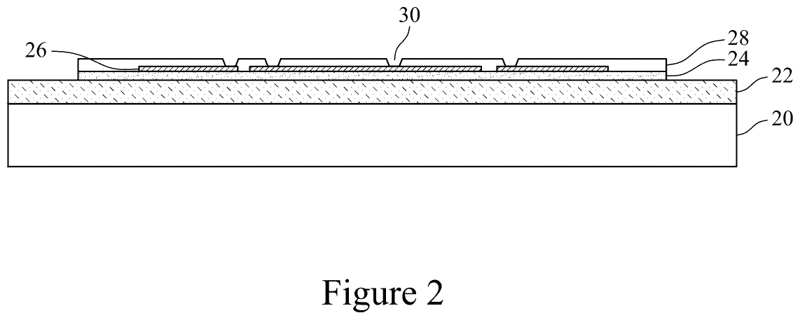

FIGS. 2 through 5 illustrate the formation of one or more additional layers of insulating material and RDLs. The respective process is illustrated as process 208 in the process flow 200 as shown in FIG. 21. Referring to FIG. 2, insulating layer 28 is formed and patterned on RDLs 26. The bottom surface of insulating layer 28 is in contact with the top surfaces of RDLs 26 and insulating layer 24. In some embodiments, insulating layer 28 is formed of or comprises an organic or inorganic material, which may be selected from the same group of candidate materials for forming insulating layer 24. Insulating layer 28 is patterned to form openings 30 therein. Hence, some portions of RDLs 26 are exposed through the openings 30 in insulating layer 28.

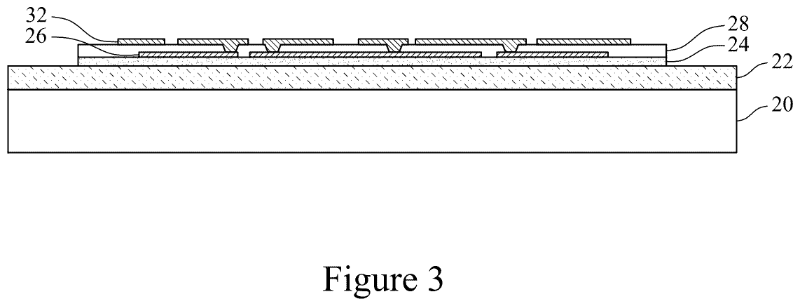

Referring to FIG. 3, RDLs 32 are formed to connect to RDLs 26. RDLs 32 include metal traces (metal lines) over insulating layer 28. RDLs 32 also include vias extending into the openings in insulating layer 28 to connect to an underlying conductive features, such as a conductive line of the RDLs 26. RDLs 32 may also formed in a plating process, wherein each of RDLs 32 includes a seed layer (not shown) and a plated metallic material over the seed layer. The seed layer and the plated material may be formed of the same material or different materials. RDLs 32 may include a metal or a metal alloy including aluminum, copper, tungsten, and/or alloys thereof.

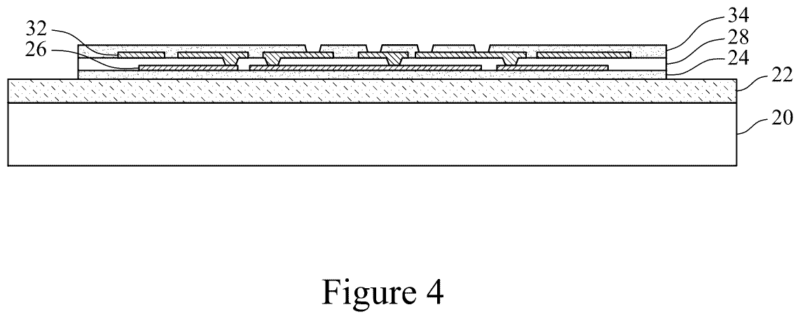

Referring to FIG. 4, insulating layer 34 is formed and patterned on RDLs 32 and insulating layer 28. Insulating layer 34 may be formed and patterned using the same or similar materials and processes as discussed above with reference to insulating layer 24.

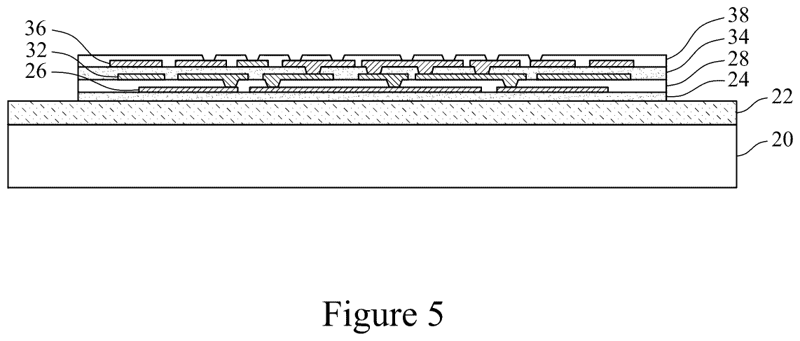

FIG. 5 illustrates the formation of RDLs 36, which are electrically connected to respective conductive features of the RDLs 32. The formation of RDLs 36 may adopt the methods and materials similar to that of the underlying RDLs 32 and 26. Next, insulating layer 38 is formed and patterned on RDLs 36. It is appreciated that although in the illustrated example embodiments, three layers of RDLs (26, 32, and 36) are illustrated as an example, the package may have any number of RDL layers such as one layer, two layers, or more than three layers, depending on the routing requirement. In some embodiments, insulating layer 38 is formed of same or similar materials/processes as discussed above with reference to insulating layer 24.

FIGS. 6-9 illustrate the formation of Under-Bump Metallurgies (UBMs) 42 and supporting structures 43. The respective process is illustrated as process 210 in the process flow 200 as shown in FIG. 21. The locations of the openings (shown in FIG. 5) in insulating layer 38 correspond to the locations in which UBMs 42 are to be formed for connecting package components 50 in a subsequent step. Supporting structures 43 may provide support to nearby regions of the subsequently formed encapsulant 60 in order to prevent or reduce cracking and/or delamination of encapsulant 60 in the nearby regions.

Referring to FIG. 6, a seed layer 35 formed in on the remaining portions of insulating layer 38 and on the exposed portions of RDLs 36. In some embodiments, seed layer 35 is a metal layer, which may be a single layer or a composite layer comprising a plurality of sub-layers formed of different materials. For example, seed layer 35 may comprise a titanium layer and a copper layer over the titanium layer. The seed layer may be formed using PVD or the like.

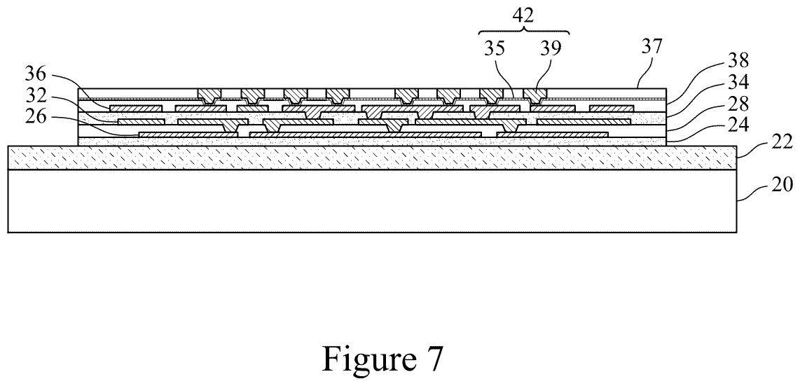

In FIG. 7, a first mask 37 is formed and patterned on seed layer 35. First mask 37 may be a layer of photoresist and/or one or more layers of dielectric material, such as one or more layers of silicon oxide, silicon nitride, silicon oxycarbide, silicon oxycarbonitride, or the like. In some embodiments first mask 37 is a photoresist formed by spin coating or the like, which is patterned by exposing the photoresist to light in accordance with a desired pattern. The patterning forms openings through the mask to expose seed layer 35, wherein the locations of the openings correspond to the locations of UBMs 42 to be formed. A conductive feature 39 is formed in the openings of first mask 37 and on the exposed portions of seed layer 35. Conductive feature 39 may be formed by plating, such as electroplating or electro-less plating, or the like using material such as nickel, copper, titanium, or multi-layers thereof. Conductive feature 39 and the underlying seed layer 35 are collectively referred to as UBMs 42. First mask 37 may be removed after forming conductive feature 39. In embodiments in which first mask 37 is a photoresist, first mask 37 is removed by an acceptable ashing or stripping process, such as using an oxygen plasma or the like. In embodiments in which first mask 37 is one or more layers of dielectric material, first mask 37 is removed by an acceptable stripping process, such as wet or dry etching.

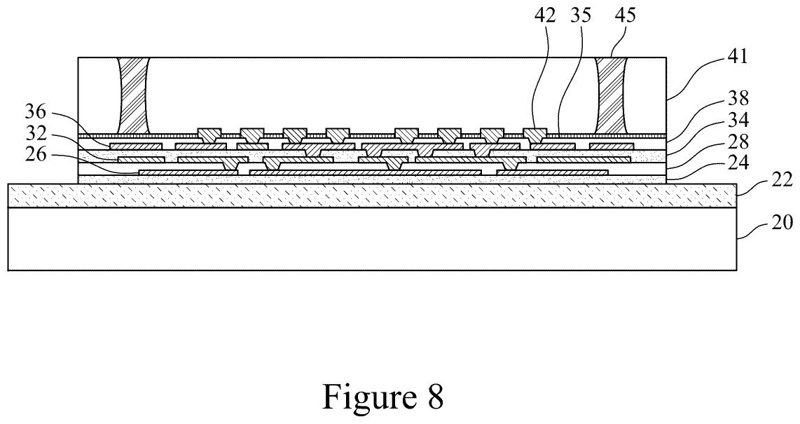

In FIG. 8, a second mask 41 is formed and patterned on seed layer 35 and UBMs 42 using similar processes and materials used to form and pattern first mask 37, where the patterning of second mask 41 forms openings through second mask 41 to expose seed layer 35 at locations corresponding to the locations at which supporting structures 43 are to be formed. A conductive feature 45 is formed in the openings of second mask 41 and on the exposed portions of seed layer 35. In some embodiments, the openings through second mask 41 may have curved sidewalls due to the patterning process, which may result in conductive feature 45 having a shape of a concave lens with curved sidewalls and varying widths, as shown in FIG. 8. Conductive feature 45 may be formed by plating, such as electroplating or electro-less plating, or the like using material with a Young's modulus greater than about 50 GPa, such as copper, nickel, or the like. As discussed in greater details below, using material with a Young's modulus greater than about 50 GPa to form the conductive feature 45 may result in later formed supporting structures 43 having a high degree of hardness, which may help to prevent or reduce cracking and/or delamination of later formed encapsulant 60. Using materials having a Young's modulus less than 50 GPa may not prevent or reduce cracking and/or delamination.

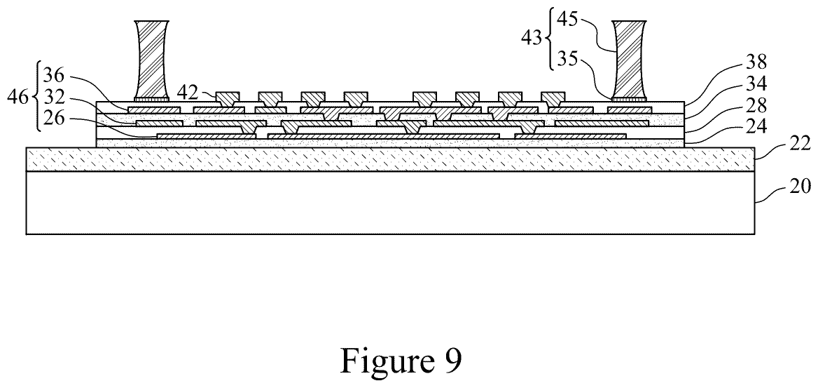

In FIG. 9, second mask 41 used is removed by an acceptable ashing, stripping, or etching process, such as ones similar to the ones used to remove first mask 37. Once second mask 41 is removed, exposed portions of seed layer 35 are removed by using an acceptable etching process, such as by wet or dry etching. Conductive feature 45 and the underlying seed layer 35 are collectively referred to as supporting structures 43.

The description above discussed a method to form UBMs 42 before forming supporting structures 43. Other possible methods including forming supporting structures 43 before UBMs 42 as well as forming UBMs 42 and supporting structures 43 at the same time. Throughout the description, the combined structure formed on release film 22, excluding supporting structures 43, is referred to as interposer 46. When insulating layers 24, 28, 34, and 38 are formed of or comprise an organic material(s) such as an organic polymer(s), interposer 46 is also referred to as an organic interposer.

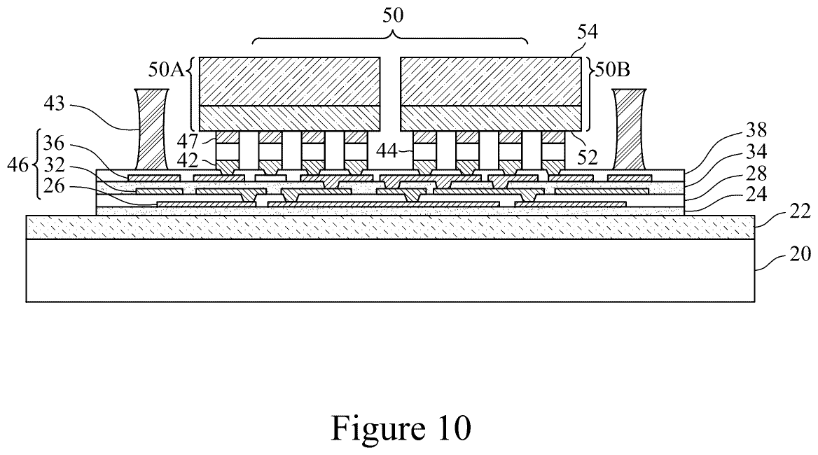

Referring to FIG. 10, package components 50A and 50B (collectively or individually referred to as package components 50) are bonded to interposer 46. The respective process is illustrated as process 212 in the process flow 200 as shown in FIG. 21. Each of package components 50 may be a device die, a package with a device die(s) packaged therein, a System-on-Chip (SoC) die including a plurality of device dies packaged as a system, or the like. The device dies in package components 50 may be or may comprise logic dies, memory dies, input-output dies, Integrated Passive Devices (IPDs), or the like, or combinations thereof. For example, the logic device dies in package components 50 may be Central Processing Unit (CPU) dies, Graphic Processing Unit (GPU) dies, mobile application dies, Micro Control Unit (MCU) dies, BaseBand (BB) dies, Application processor (AP) dies, or the like. The memory dies in package components 50 may include Static Random Access Memory (SRAM) dies, Dynamic Random Access Memory (DRAM) dies, or the like. The device dies in package components 50 may include semiconductor substrates and interconnect structures, which are represented by semiconductor substrate 52 and interconnect structure 54, respectively, in FIG. 10 as an example. Semiconductor substrate 52 may include external connectors 47.

In some embodiments, the package components 50A and 50B are bonded to the interposer 46 using electrical connectors 44, such as solder. For example, solder may be placed on external connectors 47 of package components 50A and 50B or the UBMs 42, and package components 50A and 50B may be placed on the UBMs 42 and a reflow process performed. Electrical connectors 44 may also include non-solder metal pillars, or metal pillars and solder caps over the non-solder metal pillars, which may also be formed through plating. Other types of bonding, such as metal-to-metal direct bonding, hybrid bonding (including both of dielectric-to-dielectric bonding and metal-to-metal direct bonding), or the like may also be used.

It is appreciated that while FIG. 10 illustrates two package components (e.g., package component 50A and 50B) attached to interposer 46, other numbers of package components may be attached. For example, one package component or more than two package components may be attached to interposer 46.

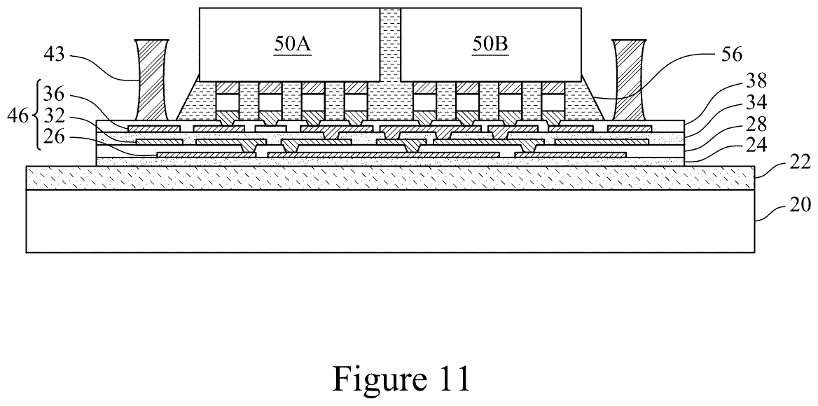

Referring to FIG. 11, underfill 56 is formed between package components 50 and interposer 46 to reduce stress and protect the joints between the package components 50 and interposer 46 (e.g., electrical connectors 44), in accordance with some embodiments. The respective process is illustrated as process 214 in the process flow 200 as shown in FIG. 21. In some embodiments, underfill 56 includes a base material, such as an epoxy, and filler particles in the epoxy, and may be deposited by a capillary flow process after the package components 50 are attached or may be formed by a suitable deposition method before the package components 50 are attached. For example, underfill 56 may be dispensed from one side of package components 50, and flows into the gaps between package components 50 and interposer 46, and into the gaps between neighboring package components 50 through capillary action. Underfill 56 may be cured. FIG. 11 shows an embodiment where underfill 56 has a flat top surface level with top surfaces of package components 50. In some embodiments, the top surface of underfill 56 may not be flat and may be lower than the top surfaces of package components 50.

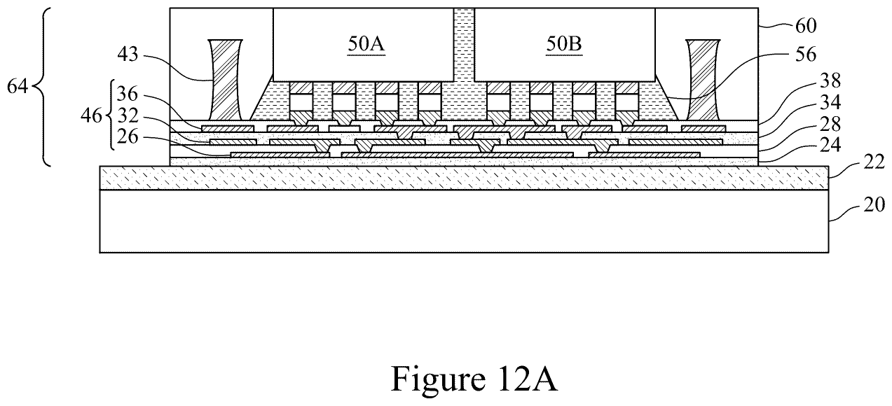

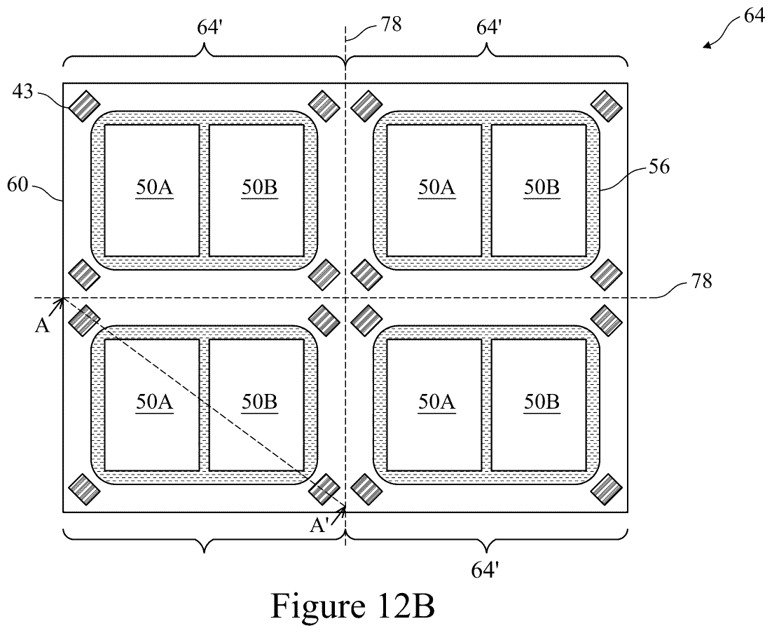

Referring to FIG. 12A, package components 50 and supporting structures 43 are encapsulated in encapsulant 60. The respective process is illustrated as process 216 in the process flow 200 as shown in FIG. 21. Encapsulant 60 covers neighboring package components 50 and supporting structures 43 fills the gaps between neighboring package components 50 and supporting structures 43. Encapsulant 60 may be formed of or comprises a molding compound, a molding underfill, an epoxy, a resin, or the like. In some embodiments, the Young's modulus of encapsulant 60 is less than the Young's modulus of supporting structure 43. For example, in embodiments in which the Young's modulus of supporting structure 43 is greater than about 50 GPa, the Young's modulus of encapsulant 60 may be in a range from about 10 GPa to about 30 GPa, such as about 10 GPa. When supporting structures 43 have a Young's modulus greater than about 50 GP, therefore a high degree of hardness, supporting structures 43 may provide support to nearby regions of encapsulant 60 in order to prevent or reduce cracking and/or delamination of encapsulant 60 in the nearby regions. When supporting structures 43 have a Young's modulus smaller than about 50 GPa, supporting structures 43 may not provide enough support to nearby regions of encapsulant 60 to prevent or reduce cracking and/or delamination of encapsulant 60 in the nearby regions. In some embodiments, encapsulant 60 may include a base material, which may be a polymer, a resin, an epoxy, or the like, and filler particles in the base material. The filler particles may include dielectric particles of SiO₂, Al₂O₃, silica, or the like, and may have spherical shapes. Also, the spherical filler particles may have the same or different diameters.

Encapsulant 60 may be applied by compression molding, transfer molding, or the like, and may be formed over interposer 46 such that supporting structures 43 and/or package components 50 are buried or covered. Encapsulant 60 may be further formed in gap regions (if any) between package components 50. Encapsulant 60 may be applied in liquid or semi-liquid form and subsequently cured, for example, at a temperature in a range between about 120° C. and about 180° C.

A planarization process may be performed on encapsulant 60 to expose upper surfaces of one or more package components 50. Upper surfaces of package components 50 and encapsulant 60 are substantially coplanar after the planarization process within process variations. Supporting structures 43 may remain embedded in encapsulant 60 after the planarization process. The planarization process may be, for example, a chemical-mechanical polish (CMP), a grinding process, or the like. In some embodiments, the planarization may be omitted. In some embodiments, encapsulant 60 may remain over one or more or all package components 50. Additionally, FIG. 12A illustrates an embodiment in which package component 50A has a same height from the interposer 46 as package component 50B. In some embodiments, package components 50 may have different heights, and encapsulant 60 may cover one or more or all package components 50. Throughout the description, the combined structure formed on release film 22 are collectively referred to as wafer structure 64.

As noted above, the processes discussed above may be performed on a wafer level and may be singulated to form separate packages. For example, FIG. 12B illustrates a top view of a portion of a wafer structure 64 having four package structures 64′, with each package structure 64′ representing a structure such as that discussed above with reference to FIGS. 1-12A. Neighboring package structures 64′ will be separated in subsequent processing along scribe lines 78. The cross-sectional view shown in FIGS. 1-12A may be obtained from the reference cross-section A-A′ in FIG. 12B, wherein top surfaces of features that are embedded in encapsulant 60, such as supporting structures 43 and underfill 56, are shown in FIG. 12B for illustrative purposes. Package structures 64′ may all be identical to each other or comprise a plurality of different designs. FIG. 12B shows one supporting structure 43, with a rectangle-shaped top surface, disposed at an angle at each corner of each of package structures 64′ as an example. The locations, shapes, sizes, and arrangements of supporting structures 43 will be discussed in greater detail later.

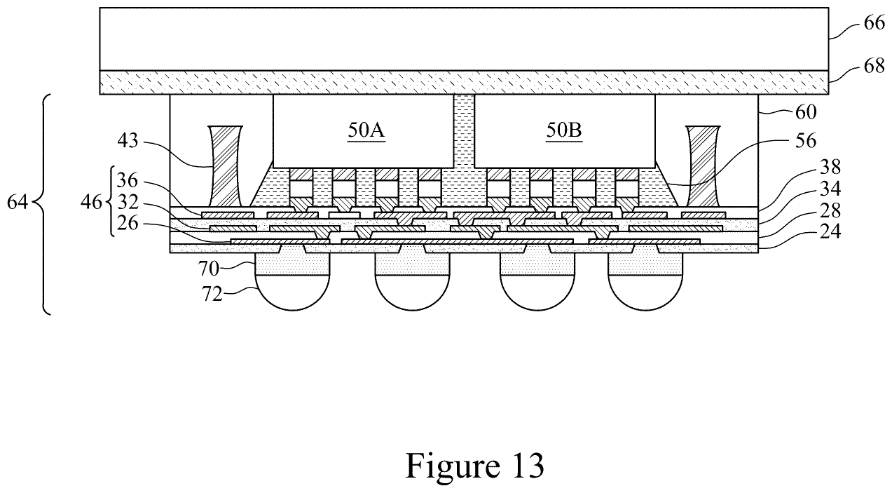

FIG. 13 illustrates a carrier swap and the formation of bottom-side electrical connectors on the bottom side of interposer 46. The respective process is illustrated as process 218 in the process flow 200 as shown in FIG. 21. A carrier 66 is attached to an upper surface of encapsulant 60 and an upper surface of package components 50 (if exposed) using release film 68. Carrier 20, shown in FIG. 12A, is detached from wafer structure 64. The detaching process may include projecting a light beam, such as a laser beam, on release film 22, shown in FIG. 12A, and the light beam penetrates through the carrier 20, which may be transparent. As a result of the light-exposure, such as the laser scanning, release film 22 is decomposed by the heat of the light beam, and carrier 20 may be lifted off from release film 22. The corresponding process is also referred to as the de-bonding.

As a result of the de-bonding process, insulating layer 24 is revealed. UBMs 70 and electrical connectors 72 are formed on interposer 46. The respective process is illustrated as process 220 in the process flow 200 as shown in FIG. 21. The formation process may include patterning insulating layer 24 to reveal the conductive pads in RDLs 26, and forming UBMs 70, which extend into the openings in insulating layer 24. UBMs 70 may be formed of or comprise nickel, copper, titanium, or multi-layers thereof. In some embodiments, each of UBMs 70 includes a titanium layer and a copper layer over the titanium layer.

Electrical connectors 72 are formed on UBMs 70. The formation of electrical connectors 72 may include placing solder balls on the exposed portions of UBMs 70, and reflowing the solder balls, and hence electrical connectors 72 are solder regions. Electrical connectors 72 may also include non-solder metal pillars, or metal pillars and solder caps over the non-solder metal pillars, which may also be formed through plating.

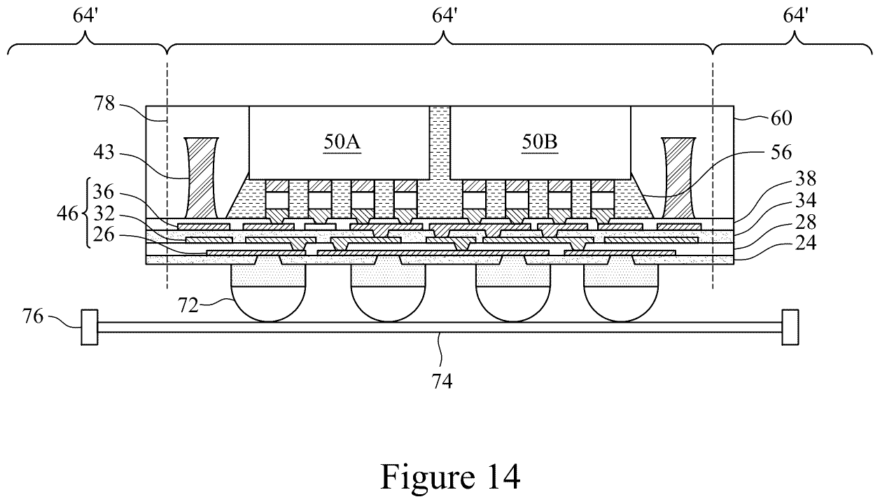

Referring to FIG. 14, wafer structure 64 is demounted from carrier 66, shown in FIG. 13, for example, by projecting a laser beam on release film 68, so that release film 68 decomposes. The respective process is illustrated as process 222 in the process flow 200 as shown in FIG. 21. The wafer structure 64 is placed on tape 74, which is supported by frame 76. Wafer structure 64 is singulated along scribe lines 78, so that wafer structure 64 is separated into discrete package structures 64′. The respective process is illustrated as process 224 in the process flow 200 as shown in FIG. 21.

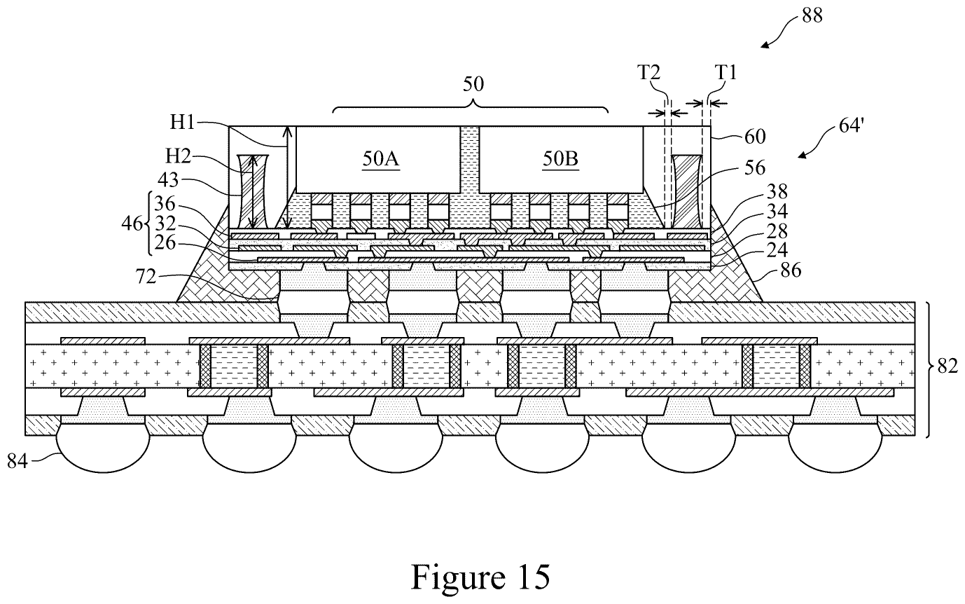

Referring to FIG. 15, package structure 64′ is bonded with package component 82 to form package 88. The bonding is via electrical connectors 72, which may include solder regions. The respective process is illustrated as process 226 in the process flow 200 as shown in FIG. 21. Package component 82 may be or may comprise an interposer, a package, a core substrate, a coreless substrate, a printed circuit board, or the like. FIG. 15, shows an embodiment where package component 82 is a core substrate, including core material, conductive vias, fill material, redistribution structures, and electrical connectors. FIG. 15 shows one layer of RDLs in each redistribution structure on each side of the core material for illustrative purposes. The core substrate may have more than one layer of RDLs in each redistribution structure. Underfill 86 may be dispensed into the gap between package structure 64′ and package component 82.

Still referring to FIG. 15, in some embodiments, the height of encapsulant 60 H1 over the interposer 46 may be in a range between about 0.2 mm and about 1 mm, the height of supporting structures 43 H2 over the interposer 46 may be in a range between about 0.02 mm and about 0.9 mm. A ratio of H2 to H1 may be in a range between about 0.1 and about 0.9, wherein a layer of encapsulant 60 may be disposed over each supporting structure 43. FIG. 15 also shows that each supporting structure 43 is spaced apart from an edge of package structure 64′ by a layer of encapsulant 60, which may have a thickness T1 in a range between about 0.05 mm and about 0.1 mm, and each supporting structure 43 is spaced apart from an edge of underfill 56 by a layer of encapsulant 60, which may have a thickness T2 in a range between about 0.05 mm and about 0.1 mm. Having layers of encapsulant 60 on the outer sides of supporting structures 43, so that supporting structures 43 are embedded in encapsulant 60, may prevent oxidization and erosion of supporting structures 43.

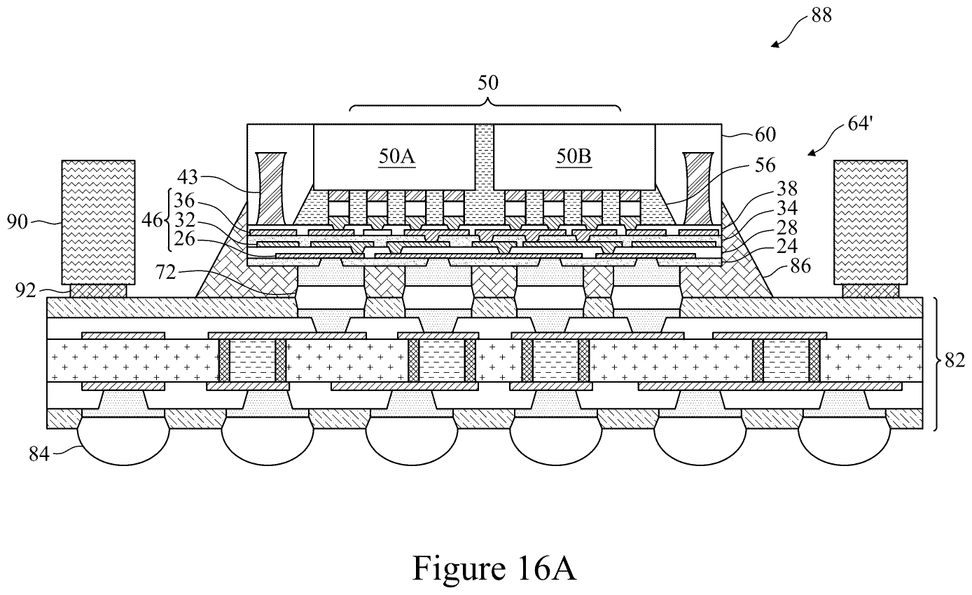

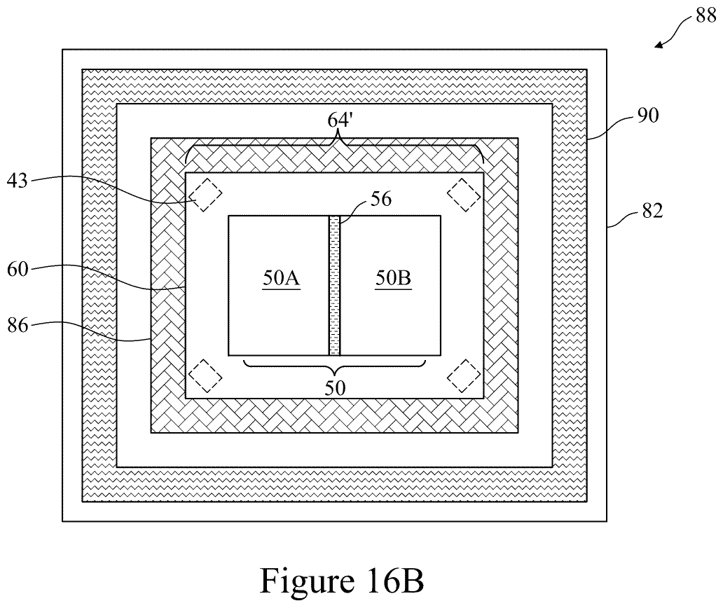

Referring to FIG. 16A, stiffener ring 90 is formed on package component 82, in accordance with some embodiments. The respective process is illustrated as process 228 in the process flow 200 as shown in FIG. 21. Stiffener ring 90 is used to provide additional support to package component 82 during subsequent manufacturing processes and usage. Stiffener ring 90 may be placed so that stiffener ring 90 is laterally separated from package structure 64′ and may encircle package structure 64′, thereby forming a cavity between package structure 64′ and stiffener ring 90. In some embodiments, stiffener ring 90 may comprise a dielectric material (e.g., silicone, or other suitable dielectric material), a metal (e.g., copper, aluminum, or other suitable metal), or the like. Stiffener ring 90 may be attached utilizing an adhesive 92 such as an epoxy, glue, polymeric material, solder paste, thermal adhesive, or the like. FIG. 16B shows a top view of package 88 shown in FIG. 16A, wherein stiffener ring 90 extends to encircle package structure 64′.

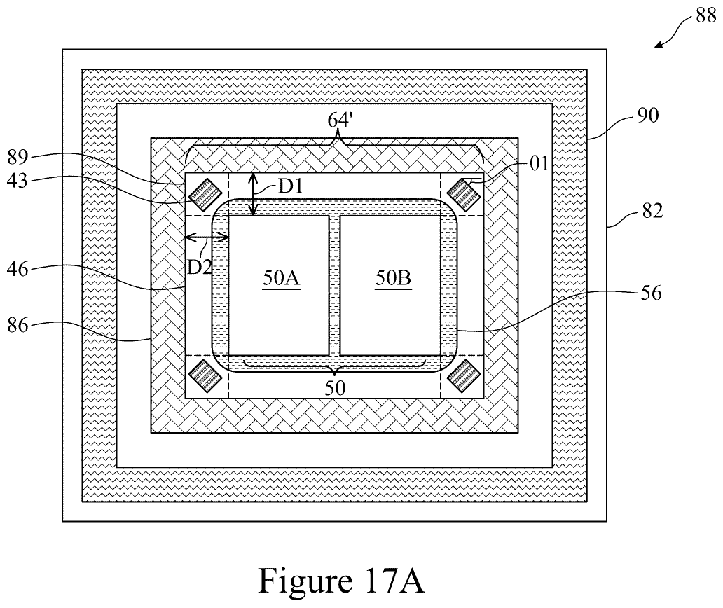

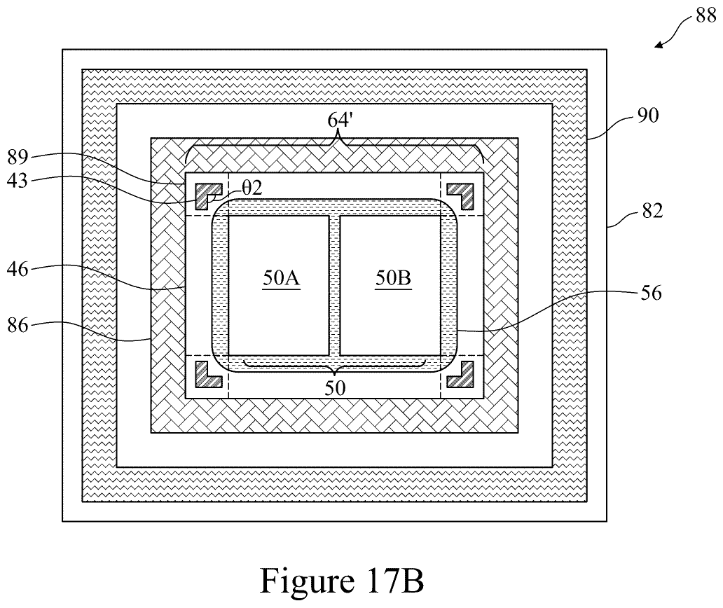

FIGS. 17A and 17B illustrates top views of package 88 shown in FIG. 16A with supporting structures 43 of varying shapes in accordance with some embodiments. Encapsulant 60 is not shown for illustrative purposes so that interposer 46, supporting structures 43, underfill 56 are revealed. A supporting structure 43 is disposed at each of the four corners of interposer 46 and spaced apart from the edges of interposer 46 and underfill 56. A top surface of each supporting structure 43 (e.g., the supporting structure 43 shown in FIGS. 17A and/or 17B) may have an area A1. In FIG. 17A, an angle θ1 between a side of the top surface of each supporting structure 43 and a side of interposer 46 may be in a range between about 35° and about 55°, such as about 45°.

FIG. 17B illustrates an embodiment in which a top surface of each supporting structure 43 is bracket-shaped or L-shape. The bracket-shaped top surface of each supporting structure 43 has two arms, which may be extending away from each correspond corner of interposer 46. An angle θ2 between the two arms, which may be facing underfill 56, may be equal to or greater than 90° and smaller than 180°. A ratio of the lengths of the two arms may be in a range between about 1 and about 1.5, such as about 1. FIGS. 17A and 17B show the embodiments wherein supporting structures 43 disposed on a same interposer 46 are identical. In some embodiments, supporting structures 43 disposed on the same interposer 46 may be the same or different.

Package components 50 are spaced apart from the horizontal sides of interposer 46 by a distance D1, which may be in a range between about 0.5 mm to about 2 mm, and are spaced apart from the vertical sides of interposer 46 by a distance D2, which may be in a range between about 0.5 mm to about 2 mm. Corner regions 89 (rectangle-shaped regions marked by dotted lines in FIGS. 17A and 17B) represented by rectangle-shaped regions disposed at each of the four corners of interposer 46, and each corner region 89 may have an area A2. A ratio of A1 to A2 may be in a range between about 0.1 and about 0.9 and each supporting structure 43 may be confined within each corresponding corner region 89.

In some embodiments, supporting structures 43 reduces the stress that may be caused by a difference in the Coefficient of Thermal Expansion (CTE) values of the various elements, such as package components 50, interposer 46 (shown in FIG. 15), and package component 82, thereby preventing or reducing cracking and/or delamination of encapsulant 60. As discussed above, when supporting structures 43 have a Young's modulus greater than about 50 GP, therefore a high degree of hardness, supporting structures 43 may provide support to nearby regions of encapsulant 60. When supporting structures 43 are disposed in corner regions 89 and embedded in encapsulant 60, supporting structures 43 may help to prevent or reduce cracking and/or delamination of encapsulant 60 in the corner regions of encapsulant 60.

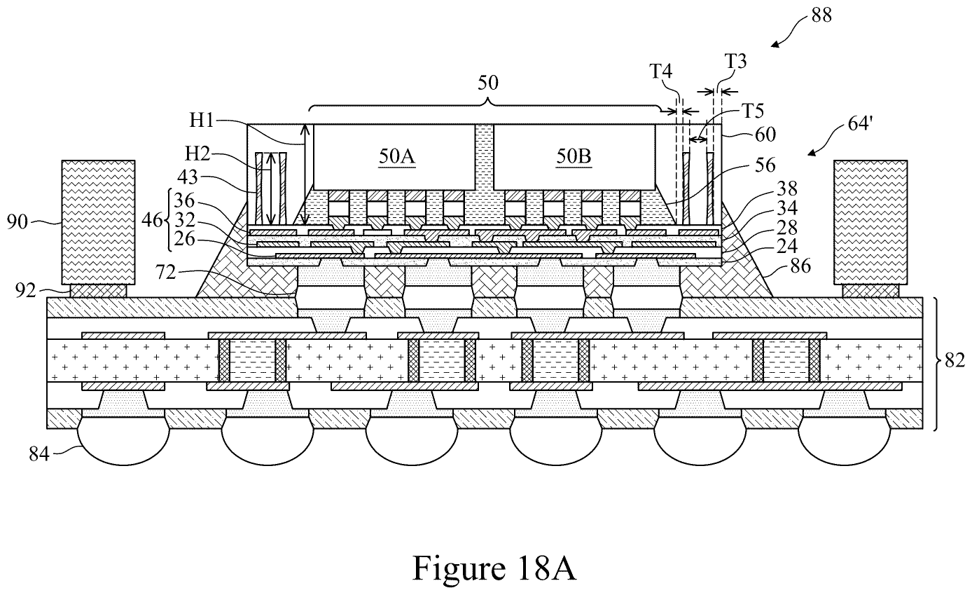

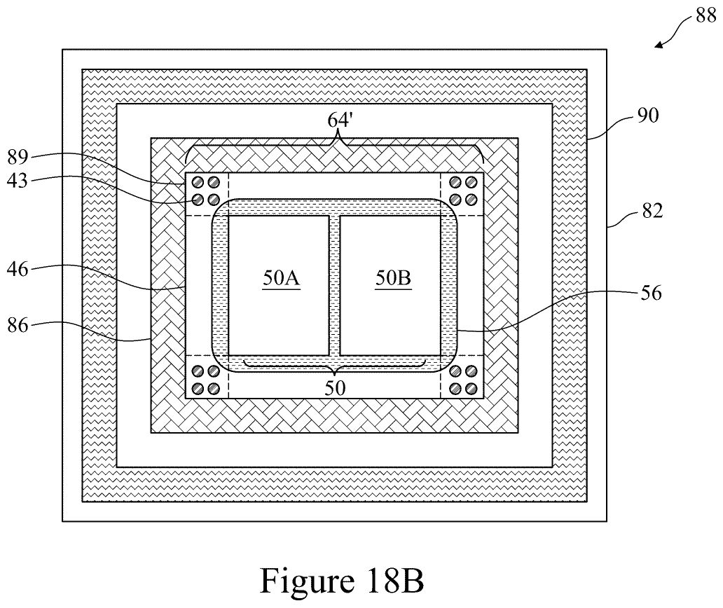

The supporting structure 43 discussed above illustrates embodiments in which one supporting structure 43 is disposed within each corresponding corner region 89 for illustrative purposes. In some embodiments, a plurality of supporting structures 43 may be disposed within each corresponding corner region 89. For example, FIGS. 18A and 18B illustrate a cross-sectional view and a top view, respectively, of an embodiment similar to the embodiment illustrated in FIG. 16A, wherein like reference numerals refer to like features. As illustrated in FIGS. 18A and 18B, there are a plurality of supporting structures 43 within at least one corner region 89 of interposer 46. The height of encapsulant 60 H1 from a surface of interposer 46 may be in a range between about 0.2 mm and about 1 mm, the height of supporting structures 43 H3 from a surface of interposer 46 may be in a range between about 0.02 mm and about 0.9 mm. A ratio of H3 to H1 may be in a range between about 0.1 and about 0.9, wherein a layer of encapsulant 60 may be disposed over each supporting structure 43. FIG. 18A also shows that a supporting structure 43, adjacent an edge of package structure 64′, is spaced apart from the edge of package structure 64′ by a layer of encapsulant 60, which may have a thickness T3 in a range between about 0.05 mm and about 0.1 mm, and a supporting structure 43, adjacent an edge of underfill 56, is spaced apart from the edge of underfill 56 by a layer of encapsulant 60, which may have a thickness T4 in a range between about 0.05 mm and about 0.1 mm. The two supporting structures 43 discussed above may be separated by a layer of encapsulant 60, which may have a thickness T5 in a range between about 0.1 mm and about 0.2 mm. Having layers of encapsulant 60 on the outer sides of supporting structures 43, so that supporting structures 43 are embedded in encapsulant 60, may prevent oxidization and erosion of supporting structures 43.

Encapsulant 60 is not shown in FIG. 18B for illustrative purposes so that interposer 46, supporting structures 43, underfill 56 are revealed. A plurality of supporting structures 43 are disposed in each corresponding corner region 89 and spaced apart to the edges of interposer 46 and underfill 56. Though FIG. 18B shows four supporting structures 43 in each corresponding corner region 89, any number is possible. A top surface of each supporting structure 43 may be a circle and may have a diameter in a range between about 0.15 mm to about 0.25 mm, although other shapes and sizes are possible. The sum of the areas of top surfaces of the four supporting structures 43 in one corner region 89 is A4. As discussed with reference to FIG. 17A, corner regions 89 are rectangle-shaped regions disposed at each of the four corners of interposer 46, and each corner region 89 has an area A2. A ratio of A4 to A2 may be in a range between about 0.1 and about 0.9 and each cluster of supporting structure 43 may be confined within each corresponding corner region 89. FIG. 18B shows the embodiments wherein supporting structures 43 disposed on a same interposer 46 are similar. In some embodiments, supporting structures 43 disposed on the same interposer 46 may be the same or different.

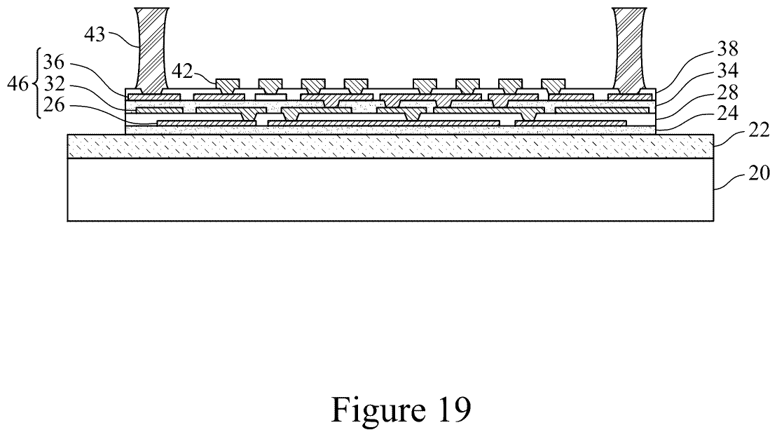

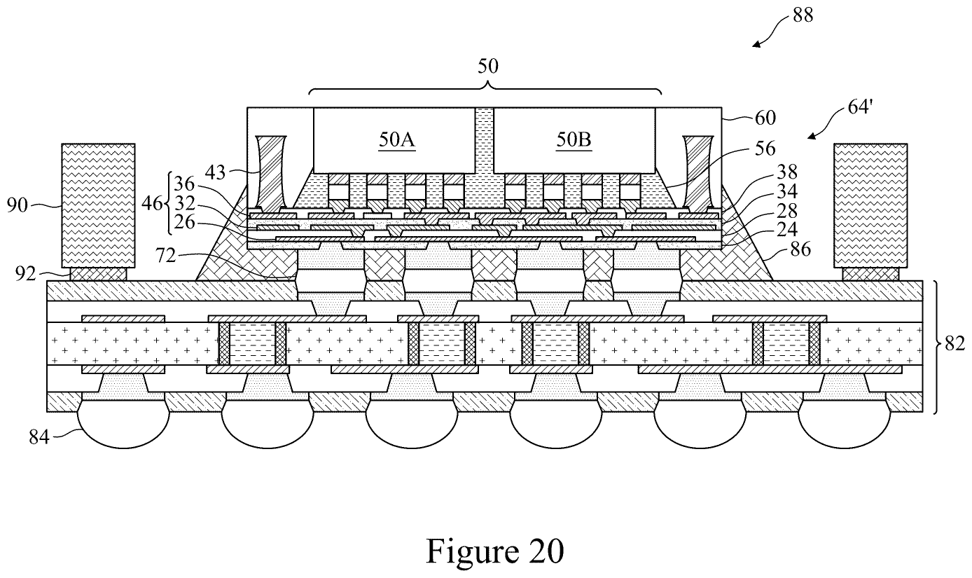

FIGS. 19-20 illustrate various manufacturing steps in accordance with some embodiments. As will be discussed in greater detail below, the supporting structure 43 is formed such that it is electrically coupled to conductive features in the interposer 46. The supporting structure 43 may be electrically floating or electrically coupled to ground. The process illustrated in FIGS. 19-20 assume processes similar to those discussed above with reference to FIGS. 1-5 were previously performed. Accordingly, after insulating layer 38 is formed as discussed above with reference to FIG. 5, processing may proceed to FIG. 19, wherein UBMs 42 and supporting structures 43 are formed on insulating layer 38. Openings are formed in insulating layer 38 to expose underlying conductive features of RDLs 36. The locations of the openings correspond to the locations in which UBMs 42 and supporting structures 43 are to be formed. The supporting structure 43 and UBMs 42 may be formed using materials and processes such as those discussed above with reference to FIG. 6, wherein supporting structures 43 in FIG. 19 protrude through the insulating layer 38 to make electrical contact to a conductive feature of the RDLs 36.

Thereafter, processes similar to those discussed above with reference to FIGS. 10-16A may be performed to form or attach, package components 50, underfill 56, encapsulant 60, package component 82, and stiffener ring 90. FIG. 20 illustrates a cross-sectional view of a device similar to the one illustrated in FIG. 16A, wherein like reference numerals refer to like features. As shown in FIG. 20, supporting structures 43 extend through insulating layer 38 and are in contact with parts of RDLs 36. Supporting structures 43 may be electrically grounded, which may reduce electrical interference with package components 50 by supporting structures 43. Supporting structures 43 are illustrated in FIGS. 19 and 20 as having a shape similar to the shape of supporting structures 43 in FIGS. 1-16B for illustrative purposes, and in some embodiments supporting structures 43 in FIGS. 19 and 20 may be formed of different shapes, sizes, and arrangements, such as those illustrated in FIGS. 17A-18B.

The embodiments of the present disclosure have some advantageous features. By selecting proper materials, quantities, sizes, and shapes for supporting structures 43 and forming supporting structures 43 at proper locations, the cracking and/or delamination of encapsulant 60 may be prevented or reduced. The prevention or reduction of cracking and/or delamination of encapsulant 60 leads to better long-term reliability of package 88.

In an embodiment, a semiconductor package includes an interposer comprising a plurality of insulating layers and a plurality of redistribution lines in the plurality of insulating layers; one or more package components bonded to the interposer, each of the one or more package components comprising a semiconductor die; an encapsulant on the interposer, wherein the encapsulant encircles the one or more package components in a top view; and a plurality of supporting structures on the interposer, wherein one or more supporting structures are disposed on each corner of the interposer in the top view, wherein the plurality of supporting structures comprise a first metal, and wherein the plurality of supporting structures are embedded in the encapsulant. In an embodiment, the first metal has a first Young's modulus and the encapsulant has a second Young's modulus, wherein the first Young's modulus is larger than the second Young's modulus. In an embodiment, the first Young's modulus is larger than 50 GPa. In an embodiment, the plurality of supporting structures have curved sidewalls in a cross-sectional view. In an embodiment, the plurality of supporting structures are electrically connected to one or more corresponding ones of the plurality of redistribution lines, wherein the plurality of supporting structures are electrically grounded. In an embodiment, a top surface of each of the plurality of supporting structures has a shape of a circle, a rectangle, or a bracket in the top view. In an embodiment, a first supporting structure of the one or more supporting structures is completely within a corner region of a first corner of the interposer in the top view, wherein the first corner of the interposer is an intersection of a first edge and a second edge of the interposer, wherein the corner region extends from the first edge of the interposer to a first line level with a first edge of a first package component of the one or more package components, the first package component being a package component of the one or more package components closest to the first corner, the first edge of the first package component being a closest edge of the first package component to the first edge of the interposer, and wherein the corner region further extends from the second edge of the interposer to a second line level with a second edge of the first package component, the second edge of the first package component being a closest edge of the first package component to the second edge of the interposer.

In an embodiment, a semiconductor package includes an interposer having a first edge and a second edge, wherein the first edge and the second edge intersect at a first corner of the interposer, the interposer further comprising: a plurality of insulating layers; and a plurality of conductive lines in the plurality of insulating layers; one or more package components bonded to a first side of the interposer, wherein each of the one or more package components comprises a semiconductor die; a first supporting structure disposed within a corner region of the first corner of the interposer, wherein the first supporting structure has a first Young's modulus, wherein the first supporting structure and all of the one or more package components are non-overlapping in a first direction parallel to the first edge, wherein the first supporting structure and all of the one or more package components are non-overlapping in a second direction parallel to the second edge; and an encapsulant encircling the one or more package components and the first supporting structure in a top view, wherein the encapsulant has a second Young's modulus smaller than the first Young's modulus. In an embodiment, the first supporting structure comprises a metal. In an embodiment, the first supporting structure is electrically connected to one of the plurality of conductive lines, wherein the first supporting structure is electrically grounded. In an embodiment, the interposer is an organic interposer. In an embodiment, the package further includes a second supporting structure disposed within the corner region of the first corner, wherein the second supporting structure and all of the one or more package components are non-overlapping in the first direction parallel to the first edge, wherein the second supporting structure and all of the one or more package components are non-overlapping in the second direction parallel to the second edge. In an embodiment, the second supporting structure is electrically connected to one of the plurality of conductive lines, wherein the second supporting structure is electrically grounded. In an embodiment, the package further includes a substrate bonded to a second side of the interposer and a stiffener ring disposed on a first side of the substrate, wherein the stiffener ring encircles the interposer in the top view.

In an embodiment, a method of manufacturing a semiconductor package, the method includes forming an interposer, wherein the interposer comprises a plurality of insulating layers and a plurality of redistribution lines in the plurality of insulating layers; forming a metal supporting structure on a first side of the interposer, the metal supporting structure being within a corner region of a first corner of the interposer in a top view; bonding one or more package components to the first side of the interposer; forming an encapsulant on the interposer, the one or more package components, and the metal supporting structure; and planarizing the encapsulant to reveal a top surface of a first package component of the one or more package components, wherein a layer of the encapsulant remains on a top surface of the metal supporting structure. In an embodiment, the forming of the metal supporting structure comprises plating copper or nickel. In an embodiment, the first corner of the interposer is an intersection of a first edge and a second edge of the interposer, wherein the corner region is rectangle-shaped in the top view, wherein a first side of the corner region is the first edge of the interposer, wherein a second side of the corner region is the second edge of the interposer, and wherein a diagonal of the corner region extends from the first corner of the interposer to a second corner of the first package component, the second corner of the first package component being a closest corner of the one or more package components to the first corner of the interposer. In an embodiment, the method further includes forming electrical connection between the metal supporting structure and one or more corresponding lines of the plurality of redistribution lines. In an embodiment, the metal supporting structure has varying widths in a cross-sectional view. In an embodiment, the method further includes bonding a substrate to a second side of the interposer and adhering a stiffener ring on a first side of the substrate, wherein the stiffener ring encircles the interposer in the top view.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package comprising:
an interposer comprising a plurality of insulating layers and a plurality of redistribution lines in the plurality of insulating layers;
one or more package components bonded to the interposer, each of the one or more package components comprising a semiconductor die;
an encapsulant on the interposer, wherein the encapsulant encircles the one or more package components in a top view; and
a plurality of supporting structures on the interposer, wherein one or more supporting structures are disposed on each corner of the interposer in the top view, wherein the plurality of supporting structures comprise a first metal, and wherein the plurality of supporting structures are embedded in the encapsulant.

2. The semiconductor package of claim 1, wherein the first metal has a first Young's modulus and the encapsulant has a second Young's modulus, wherein the first Young's modulus is larger than the second Young's modulus.

3. The semiconductor package of claim 2, wherein the first Young's modulus is larger than 50 GPa.

4. The semiconductor package of claim 1, wherein the plurality of supporting structures have curved sidewalls in a cross-sectional view.

5. The semiconductor package of claim 1, wherein the plurality of supporting structures are electrically connected to one or more corresponding ones of the plurality of redistribution lines, wherein the plurality of supporting structures are electrically grounded.

6. The semiconductor package of claim 1, wherein a top surface of each of the plurality of supporting structures has a shape of a circle, a rectangle, or a bracket in the top view.

7. The semiconductor package of claim 1, wherein a first supporting structure of the one or more supporting structures is completely within a corner region of a first corner of the interposer in the top view, wherein the first corner of the interposer is an intersection of a first edge and a second edge of the interposer, wherein the corner region extends from the first edge of the interposer to a first line level with a first edge of a first package component of the one or more package components, the first package component being a package component of the one or more package components closest to the first corner, the first edge of the first package component being a closest edge of the first package component to the first edge of the interposer, and wherein the corner region further extends from the second edge of the interposer to a second line level with a second edge of the first package component, the second edge of the first package component being a closest edge of the first package component to the second edge of the interposer.

8. A semiconductor package comprising:
an interposer having a first edge and a second edge, wherein the first edge and the second edge intersect at a first corner of the interposer, the interposer further comprising:
a plurality of insulating layers; and
a plurality of conductive lines in the plurality of insulating layers;
one or more package components bonded to a first side of the interposer, wherein each of the one or more package components comprises a semiconductor die;
a first supporting structure disposed within a corner region of the first corner of the interposer, wherein the first supporting structure has a first Young's modulus, wherein the first supporting structure and all of the one or more package components are non-overlapping in a first direction parallel to the first edge, wherein the first supporting structure and all of the one or more package components are non-overlapping in a second direction parallel to the second edge; and
an encapsulant encircling the one or more package components and the first supporting structure in a top view, wherein the encapsulant has a second Young's modulus smaller than the first Young's modulus.

9. The semiconductor package of claim 8, wherein the first supporting structure comprises a metal.

10. The semiconductor package of claim 8, wherein the first supporting structure is electrically connected to one of the plurality of conductive lines, wherein the first supporting structure is electrically grounded.

11. The semiconductor package of claim 8, wherein the interposer is an organic interposer.

12. The semiconductor package of claim 8, further comprising a second supporting structure disposed within the corner region of the first corner, wherein the second supporting structure and all of the one or more package components are non-overlapping in the first direction parallel to the first edge, wherein the second supporting structure and all of the one or more package components are non-overlapping in the second direction parallel to the second edge.

13. The semiconductor package of claim 12, wherein the second supporting structure is electrically connected to one of the plurality of conductive lines, wherein the second supporting structure is electrically grounded.

14. The semiconductor package of claim 8, further comprising a substrate bonded to a second side of the interposer and a stiffener ring disposed on a first side of the substrate, wherein the stiffener ring encircles the interposer in the top view.

15. A method of manufacturing a semiconductor package, the method comprising:
forming an interposer, wherein the interposer comprises a plurality of insulating layers and a plurality of redistribution lines in the plurality of insulating layers;
forming a metal supporting structure on a first side of the interposer, the metal supporting structure being within a corner region of a first corner of the interposer in a top view;
bonding one or more package components to the first side of the interposer;
forming an encapsulant on the interposer, the one or more package components, and the metal supporting structure; and
planarizing the encapsulant to reveal a top surface of a first package component of the one or more package components, wherein a layer of the encapsulant remains on a top surface of the metal supporting structure.

16. The method of claim 15, wherein the forming of the metal supporting structure comprises plating copper or nickel.

17. The method of claim 15, wherein the first corner of the interposer is an intersection of a first edge and a second edge of the interposer, wherein the corner region is rectangle-shaped in the top view, wherein a first side of the corner region is the first edge of the interposer, wherein a second side of the corner region is the second edge of the interposer, and wherein a diagonal of the corner region extends from the first corner of the interposer to a second corner of the first package component, the second corner of the first package component being a closest corner of the one or more package components to the first corner of the interposer.

18. The method of claim 15, further comprising forming electrical connection between the metal supporting structure and one or more corresponding lines of the plurality of redistribution lines.

19. The method of claim 15, wherein the metal supporting structure has varying widths in a cross-sectional view.

20. The method of claim 15, further comprising bonding a substrate to a second side of the interposer and adhering a stiffener ring on a first side of the substrate, wherein the stiffener ring encircles the interposer in the top view.
